(19) United States
(12) Patent Application Publication
(10) Pub. No.: US 2004/0233959 A1
(43) Pub. Date: Nov. 25, 2004

(54) Multiple wavelength semiconductor laser and manufacturing method thereof

(76) Inventor: Takahiro Arakida, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/826,085

(22) Filed: Apr. 16, 2004

(30) Foreign Application Priority Data
Apr. 24, 2003 (JP) P2003-119631

(51) Int. Cl. H01S 5/00

(52) U.S. Cl. 372/49; 372/50

(57) ABSTRACT

A multiple wavelength semiconductor laser is disclosed. The multiple wavelength semiconductor laser has a first edge emitting type resonator structure and a second edge emitting type resonator structure disposed on a common substrate through a separation region. The first edge emitting type resonator structure has an oscillation wavelength of 650 nm. The second edge emitting type resonator structure has an oscillation wavelength of 780 nm. A low reflection film that is a three-layer dielectric film composed of a first Al₂O₃ film of 60 nm, a TiO₂ film of 55 nm, and a second Al₂O₃ film of 140 nm, where the refractive index of the TiO₂ film is smaller than the refractive index of the first Al₂O₃ film and the refractive index of the second Al₂O₃ film.

### CROSS REFERENCES TO RELATED APPLICATIONS

The present document is based on Japanese Priority Document JP 2003-119631, filed in the Japanese Patent Office on Apr. 24, 2003, the entire contents of which being incorporated herein by reference.

### BACKGROUND OF THE INVENTION

1. Field of the Invention

The present invention relates to a multiple wavelength semiconductor laser that monolithically has a plurality of edge emitting type semiconductor laser devices having different wavelengths and a method for manufacturing the laser, in particular, a multiple wavelength semiconductor laser that has a common low reflection film having a desired reflectivity to different wavelengths of edge emitting type semiconductor laser devices and a method for manufacturing the laser.

2. Description of Related Art

In a case where an injection current is increased and a light output power is increased in an edge emitting type semiconductor laser device, at a time when the light output power exceeds a particular level, a phenomenon of which the light output power suddenly decreases takes place. This phenomenon results from a catastrophic optical damage (COD) that takes place on a light emitting edge of a semiconductor laser device. It is said that the COD takes place by the following mechanism.

In other words, if a current is input, a non-recombination current flows on a light emitting edge of the semiconductor laser device through a high density face state. Thus, a carrier density near the light emitting edge is lower than that inside of the laser. As a result, light is absorbed. The light absorption generates heat. And thus, the temperature near the light emitting edge rises so that band gap energy near the light emitting edge decreases, which results in further absorption of the light. By this positive feedback loop, the temperature on the light emitting edge extremely rises, and, finally, the light emitting edge melts. Consequently, the laser oscillation stops. In addition, it is said that the light absorption increases due to oxidization of the light emitting edge and occurrence of point defects such as a vacancy.

Thus, to prevent the COD from taking place, conventionally, a low reflection film has been coated on the light emitting edge so that laser light can be emitted to the outside as much as possible.

While diversifying standards and types of optical recording mediums, a recording and reproducing apparatus that records and reproduces data to and from two types of optical recording mediums having different wavelength bands of, for example, 650 nm and 780 nm has been developed.

The recording and reproducing apparatus is provided with a one-chip two-wavelength semiconductor laser that monolithically has a 650 nm band semiconductor laser element and a 780 nm band semiconductor laser element.

To prevent the COD from occurrence, if different types of low reflection films are disposed on the light emitting edges of the individual semiconductor laser devices of the two-wavelength semiconductor laser, the process for forming the low reflection films becomes complicated. On the other hand, if one common low reflection film is disposed, it should have a reflectivity low enough for both a 650 nm band of light and a 780 nm band of light.

Thus, application of the technology for one wavelength to a low reflection film of a two-wavelength semiconductor laser is difficult to accomplish an effective low reflection film for both the 650 nm band of light and the 780 nm band of light.

To solve that problem, a related art reference for example Japanese Patent Application Publication No. 2001-230495 discloses that one-layer reflection films of the same type and having a substantially same film thicknesses are formed on light emitting edges of semiconductor laser devices of which a plurality of laser resonators having different oscillation wavelengths are disposed on one substrate.

In specific, in the two-wavelength semiconductor laser having wavelength bands of 650 nm and 780 nm, an aluminum film having a refractive index of around 1.66 and a film thickness of around 470 nm is disposed as a reflection film for enabling higher output of the 650 nm laser and an aluminum film having a refractive index of around 1.66 and a film thickness of around 390 nm is disposed as a reflection film for enabling higher output of the 650 nm wavelength band laser, respectively. In other words, the related art reference has proposed that the reflectivities at the edges for different oscillation wavelengths were controlled by forming films made of one type of material on the edges of the resonators.

[Patent Document 1]

Japanese Patent Application Publication No. 2001-230495 (see FIG. 1.)

However, according to the foregoing related art reference, the reflectivities of the low reflection films for the individual wavelengths are controlled by slightly varying the thicknesses of films of the same dielectric material. Thus, if the thicknesses of the films are set in a predetermined range, the reflectivities for individual wavelengths are unconditionally defined. Accordingly, it is difficult to independently control the reflectivities for individual wavelengths.

In a case where the film thickness of a low reflection film of a two-wavelength semiconductor laser were set to 150 nm, a reflectivity for one wavelength is around 10%, whereas a reflectivity for the other wavelength is around 25%. Accordingly, in a case where low reflectivities were required for individual wavelength bands, if the thicknesses of the reflection films are tried to be the same, a combination of reflectivities for different wavelength bands would be limited to a narrow range. Thus, it is difficult to accomplish a multiple wavelength semiconductor laser having a predetermined laser characteristic.

### SUMMARY OF THE INVENTION

In view of the foregoing, it would be desirable to provide a multiple wavelength semiconductor laser that has a common low reflection film disposed on light emitting edges, the common low reflection film having predetermined reflectivities for oscillation wavelengths of individual semiconductor laser devices.

Thus, a first aspect of the present invention is a multiple wavelength semiconductor laser monolithically having a plurality of edge emitting type semiconductor laser devices having different wavelengths. The laser includes a common low reflection multiple layer film that is a three-layer dielectric film composed of a first dielectric film, a second dielectric film, and a third dielectric film that are successively formed outwardly, the common low reflection film being formed for the same film thickness on light emitting edges of the plurality of edge emitting type semiconductor laser devices. In the laser, a refractive index of the second dielectric film is larger than a refractive index of the first dielectric film and a refractive index of the third dielectric film.

According to the present invention, since the common low reflection type multiple-layer film that is the three-layer dielectric film composed of the first dielectric film, the second dielectric film, and the third dielectric film is disposed on the light emitting edges of individual semiconductor laser devices, the thicknesses of the common low reflection multiple layer film disposed on the light emitting edges being the same, a process for forming the low reflection film can be easily performed.

Appropriately setting the composition and film thickness of each dielectric film makes it easy to design a common low reflection multiple layer film having a desired reflectivity to an oscillation wavelength of each semiconductor laser device. For example, according to the present invention, appropriately selecting the film types (compositions) and film thicknesses of the first to third dielectric films makes the reflectivity of a light emitting edge for each oscillation wavelength to 15% or less.

It is not necessary that the reflectivities for oscillation wavelengths of individual semiconductor laser devices should be the same. Instead, different reflectivities can be set for oscillation wavelengths of individual semiconductor laser devices. For example, a reflectivity of 5% may be set for one semiconductor laser device, whereas a reflectivity of 10% may be set for another semiconductor laser device.

In addition, since the refractive index of the second dielectric film is larger than the reflectivity of the first dielectric film and the reflectivity of the third dielectric film, the reflectivity of the interface between the first dielectric film and the second dielectric film and the reflectivity of the interface between the second dielectric film and the third dielectric film are made to be low so that the effective reflectivity of the three-layer dielectric film can be decreased.

In the multiple wavelength semiconductor laser according to the present invention, the film thicknesses of the first dielectric film and the second dielectric film are selected. Thereafter, with a parameter of the film thickness of the third dielectric film, the reflectivity of the three-layer dielectric film for the oscillation wavelengths of the individual semiconductor laser elements is calculated. As a result, the relation between the film thickness of the third dielectric film and the reflectivity of the three-layer dielectric film is obtained.

Thereafter, based on the relation between the film thickness of the third dielectric film and the reflectivity of the three-layer dielectric film, the film thickness of the third dielectric film is selected so that the reflectivity of the three-layer dielectric film for oscillation wavelengths of a plurality of semiconductor laser devices becomes the predetermined value.

The compositions of the dielectric films are not restricted. In addition, it is not necessary that the compositions of the first to third dielectric films should be different from each other. The composition of the first dielectric film may be the same as the composition of the third dielectric film. As each of the first dielectric film to the third dielectric film, one of an Al₂O₃ film, a SiNₓ film, a SiO₂ film, a SiC film, an AlN film, and a GaN film can be selected.

The structures and oscillation wavelengths of the plurality of edge emitting type semiconductor laser devices are not restricted. The oscillation wavelengths of the plurality of edge emitting type semiconductor laser devices can be, for example, one of a 650 nm band, a 780 nm band, and a 850 nm band. In this example, the 650 nm band ranges from a wavelength of 645 nm to a wavelength of 665 nm; the 780 nm band ranges from a wavelength of 770 nm to a wavelength of 790 nm; and the 850 nm band ranges from a wavelength of 830 nm to a wavelength of 860 nm.

The present invention can be applied regardless of the compositions of a substrate and compound semiconductor layers that constitute the structure of resonators formed thereon. For example, the present invention can be suitably applied to a multiple wavelength semiconductor laser that is provided with, for example, a plurality of GaAs type, AlGaAs type, or AlGaInP type semiconductor laser devices.

In addition, the present invention can be applied regardless of the structure of a laser stripe for example a buried type or an air ridge type.

A second aspect of the present invention is a method for producing a multiple wavelength semiconductor laser monolithically having a plurality of edge emitting type semiconductor laser devices having different wavelengths, a resonator structure having been formed on a wafer, the wafer being cleaved, a laser bar being formed, a common low reflection film being disposed on light emitting edges of the plurality of edge emitting type semiconductor laser devices exposed on one cleaved facet of the laser bar. The method includes the steps of (1) selecting a first dielectric film and a third dielectric film, and then selecting a dielectric film as a second dielectric film having a refractive index that is larger than a refractive index of the first dielectric film and a refractive index of the third dielectric film so as to dispose a three-layer dielectric film composed of the first dielectric film, the second dielectric film, and the third dielectric film as the common low reflection film; (2) determining the film thicknesses of the first dielectric film and the second dielectric film; (3) calculating a reflectivity for the three-layer dielectric film for the oscillation wavelengths of the plurality of edge emitting type semiconductor laser devices with a parameter of the film thickness of the third dielectric film so as to obtain a relationship between a film thickness of the third dielectric film and a reflectivity of the three-layer dielectric film; and (4) selecting the film thickness of the third dielectric film in accordance with the relationship between the film thickness of the third dielectric film and the reflectivity of the three-layer dielectric film so that the reflectivity of the three-layer dielectric film for the oscillation wavelengths of the plurality of edge emitting type semiconductor laser devices becomes a predetermined value or less.

In the method according to the present invention, the types and film thicknesses of dielectric films are selected and set in accordance with data obtained through conventional experiences and experiments. Generally, to obtain good dielectric films, the film thicknesses of the first and second dielectric films should be set to 20 nm or more and 100 nm or less.

In a case where the relationship between the film thickness of the third dielectric film and the reflectivity of the three-layer dielectric film obtained at the step (3) does not satisfy the predetermined value or less of the reflectivity for the oscillation wavelengths at the step (4), the method further includes the steps of (5) returning to the step (2) and determining another value of at least either one of the film thickness of the first dielectric film and the film thickness of the second dielectric film; and (6) advancing to the step (3) and the step (4) and repeating a cycle of the step (2) to the step (4) until the film thickness of the third dielectric film can be selected so that the reflectivity for the oscillation wavelengths satisfies the predetermined value or less.

In a case where the relationship between the film thickness of the third dielectric film and the reflectivity of the three-layer dielectric film does not satisfy the predetermined value or less of the reflectivity for the oscillation wavelengths at the step (6), the method further includes the step of (7) returning to the step (1), selecting another dielectric film as at least one of the first dielectric film to the third dielectric film of the three-layer dielectric film, and repeating the cycle of the step (2) to the step (4).

In a case where the relationship between the film thickness of the third dielectric film and the reflectivity of the three-layer dielectric film does not satisfy the predetermined value or less of the reflectivity for the oscillation wavelengths at the step (7), the method further includes the step of (8) returning to the step (1), selecting another dielectric film as at least either one of the first dielectric film to the third dielectric film of the three-layer dielectric film, and repeating the cycle of the step (2) to the step (4).

As described above, in the method according to the present invention, since the compositions and film thicknesses of the first to third dielectric films are used as variables, there are many variables. Thus, a low reflection film having an optimum reflectivity for each semiconductor laser element can be disposed. In other words, by repeating the foregoing cycle, a low reflection film having a desired reflectivity for the oscillation wavelength of each semiconductor laser device can be designed.

In the method according to the present invention, the first to third dielectric films can be formed by a known method such as a sputtering, a chemical vapor deposition (CVD), or an electron beam (EB) evaporation. In particular, the sputtering is preferred because it allows film thicknesses to be accurately controlled.

According to the present invention, a common low reflection multiple layer film is disposed on light emitting edges of individual semiconductor laser devices. The common low reflection multiple layer film is a three-layer dielectric film composed of a first dielectric film, a second dielectric film, and a third dielectric film of which the refractive index of the second dielectric film is larger than those of the first dielectric film and the third dielectric film. If the composition and film thickness of each dielectric film are properly set, a common low reflection film that has a desired reflectivity for the oscillation wavelength of each semiconductor laser device can be easily designed.

According to the present invention, since reflectivities for the oscillation wavelengths of the individual semiconductor laser devices disposed in the multiple wavelength semiconductor laser can be combined in a wide range, the reflectivities can be controlled corresponding to the laser characteristics of the individual semiconductor laser devices.

In addition, as long as the relationship of the refractive index of the second dielectric film and the refractivities of the first and third dielectric films is satisfied as specified in the present invention, various types of materials of dielectric films can be used. Thus, a low reflection film can be easily designed and produced.

The method according to the present invention accomplishes a method for suitably producing a multiple wavelength semiconductor laser according to the present invention.

Other principle features and advantages of the present invention will become apparent to those skilled in the art upon review of the following drawing, the detailed description, and the appended claims.

### BRIEF DESCRIPTION OF THE DRAWINGS

The invention will become more fully understood from the following detailed description, taken in conjunction with the accompanying drawing, wherein like reference numerals denote like elements, in which:

FIG. 1 is a sectional view showing structures of a low reflection film and a high reflection film disposed on light emitting edges and rear edges of a multiple wavelength semiconductor laser according to a first embodiment;

FIG. 2 is a graph showing the relationship between a film thickness of a second Al₂O₃ film and reflectivities of a three-layer dielectric film for wavelengths of 650 nm and 780 nm according to the first embodiment;

FIG. 3 is a sectional view showing structures of a low reflection film and a high reflection film disposed on light emitting edges and rear edges of a multiple wavelength semiconductor laser according to a second embodiment;

FIG. 4 is a graph showing the relationship between a film thickness of a second Al₂O₃ film and reflectivities of a three-layer dielectric film for wavelengths of 650 nm and 780 nm according to the second embodiment;

FIG. 5A and FIG. 5B are sectional views showing the multiple wavelength semiconductor laser according to the first embodiment at two manufacturing steps;

FIG. 6 is a flow chart showing steps at which a structure of a low reflection film is set in a method according to a third embodiment of the present invention; and

FIG. 7 is a graph showing a range of the film thickness of the second Al₂O₃ film whose reflectivity is 15% or less in the graph shown in FIG. 2.

### DESCRIPTION OF THE PREFERRED EMBODIMENTS

Next, with reference to the accompanying drawings, embodiments of the present invention will be described in detail.

(First Embodiment—Multiple Wavelength Semiconductor Laser)

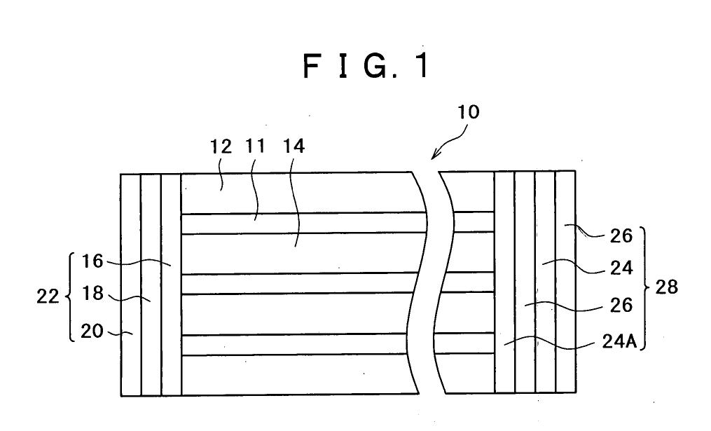

The first embodiment is an example of a multiple wavelength semiconductor laser according to the present invention. FIG. 1 is a sectional view showing structures of a low reflection film and a high reflection film disposed on light emitting edges and rear edges of a multiple wavelength semiconductor laser according to the first embodiment.

As shown in FIG. 1, a multiple wavelength semiconductor laser 10 is a multiple wavelength semiconductor laser that has a first edge emitting type resonator structure (first semiconductor laser element) 12 having an oscillation wavelength of 650 nm and a second edge emitting type resonator structure (second semiconductor laser element) 14 having an oscillation wavelength of 780 nm. The first resonator structure 12 and the second resonator structure 14 are disposed on a common substrate (not shown) through a separation region 11. FIG. 1 shows a multiple wavelength semiconductor laser as a laser bar of which a material wafer is cleaved. In FIG. 1, the left side edges are light emitting edges.

On the light emitting edges of the first resonator structure 12 and the second resonator structure 14, a low reflection film 22 is disposed. The low reflection film 22 is a three-layer dielectric film composed of a first Al₂O₃ film 16 of 60 nm, a TiO₂ film 18 of 55 nm, and a second Al₂O₃ film 20 of 140 nm are formed in succession outwardly.

The TiO₂ film 18 is disposed as a second dielectric film. The TiO₂ film 18 has a refractive index of 2.00. As specified in the present invention, the refractive index of the TiO₂ film 18 is larger than the refractive index of the first Al₂O₃ film 16 as a first dielectric film and the refractive index of the second Al₂O₃ film 20 as a third dielectric film. The refractive index of the second Al₂O₃ film 20 is 1.65.

On the opposite side of the light emitting edges, a high reflection film 28 is disposed. The high reflection film 28 is a four-layer film composed of two Al₂O₃ films 24 and two a-Si films 26 that are alternately formed. The Al₂O₃ film 24 and the a-Si film 26 have a film thickness of λ/4 n₁ (where λ is 720 nm and n₁ represents the refractive index of the Al₂O₃ film) and a film thickness of λ/4 n₂ (where λ is 720 nm and n₂ represents the refractive index of the a-Si film), respectively, for a wavelength of around 720 nm, which is an intermediate value of 650 nm and 780 nm. The reflectivity of the high reflection film 28 is 95%.

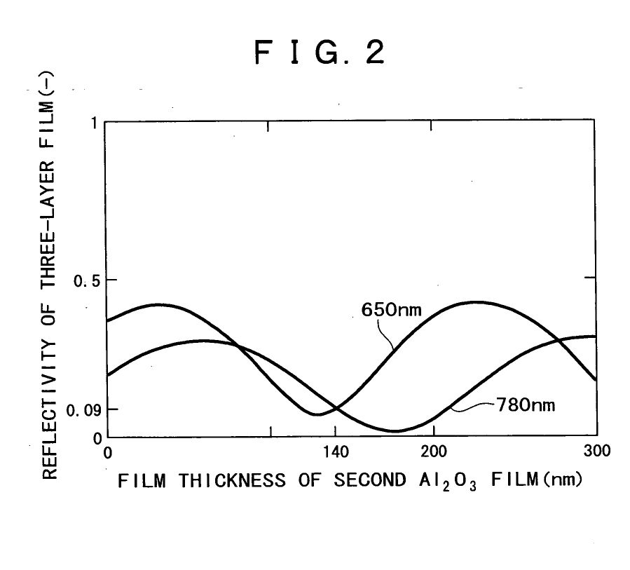

As is clear from FIG. 2 that shows the relationship between the film thickness of the second Al₂O₃ film 20 and the reflectivity of the three-layer dielectric film, according to the first embodiment, since the low reflection film 22 is constituted in the above-mentioned manner, the low reflection film 22 has a low reflectivity of 9% for both oscillation wavelengths of 650 nm and 780 nm.

FIG. 2 is a graph showing the reflectivity of the three-layer dielectric film for wavelengths of 650 nm and 780 nm with a parameter of the film thickness of the second Al₂O₃ film 20 in a case that the film thickness of the first Al₂O₃ film 16 and the film thickness of the TiO₂ film 18 are set to 60 nm and 55 nm, respectively.

Assuming that like the foregoing low reflection film 22, the film thicknesses of the first Al₂O₃ film 16 and the TiO₂ film 18 are set to 60 nm and 55 nm, respectively and unlike the low reflection film 22, the film thickness of the second Al₂O₃ film 20 is set to 100 nm, from the graph shown in FIG. 2, as the low reflection film, a three-layer dielectric film having a reflectivity of 19% for a wavelength of 650 nm or a reflectivity of 25% for a wavelength of 780 nm can be obtained.

In addition, assuming that like the low reflection film 22, the film thicknesses of the first Al₂O₃ film 16 and the TiO₂ film 18 are set to 60 nm and 55 nm, respectively and unlike the low reflection film 22, the film thickness of the second Al₂O₃ film 20 is set to 175 nm, from the graph shown in FIG. 2, as the low reflection film, a three-layer dielectric film having a reflectivity of 25% for a wavelength of 650 nm and a reflectivity of 2% for a wavelength of 780 nm can be obtained.

(Second Embodiment—Multiple Wavelength Semiconductor Laser)

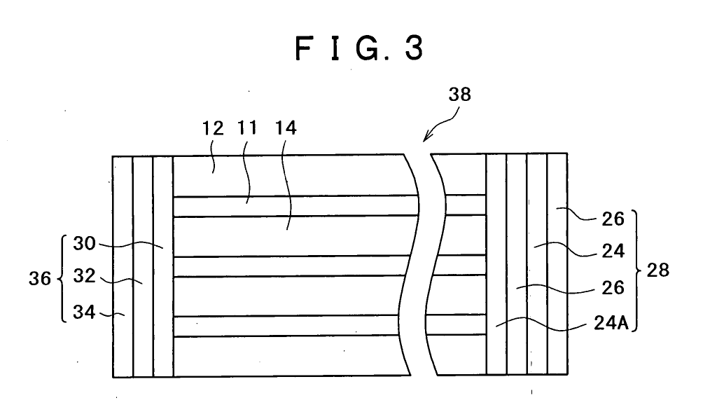

A second embodiment of the present invention is another example of a multiple wavelength semiconductor laser according to the present invention. FIG. 3 is a sectional view showing structures of a low reflection film and a high reflection film formed on light emitting edges and rear edges of the multiple wavelength semiconductor laser according to the second embodiment.

Like the first embodiment, a multiple wavelength semiconductor laser 38 according to the second embodiment is a multiple wavelength semiconductor laser that has a first edge emitting type resonator structure (first semiconductor laser element) 12 having an oscillation wavelength of 650 nm and a second edge emitting type resonator structure (second semiconductor laser element) 14 having an oscillation wavelength of 780 nm. The first resonator structure 12 and the second resonator structure 14 are disposed on a common substrate (not shown) through a separation region 11. The structure of the multiple wavelength semiconductor laser 38 is the same as the structure of the multiple wavelength semiconductor laser according to the first embodiment except for the structure of the low reflection film disposed on the light emitting edges.

On the light emitting edges of the first resonator structure 12 and the second resonator structure 14, a low reflection film 36 is disposed. The low reflection film 36 is a three-layer dielectric film composed of a first Al₂O₃ film 16 of 30 nm, a TiO₂ film 32 of 55 nm, and a second Al₂O₃ film 34 of 100 nm are formed in succession outwardly.

On the opposite side of the light emitting edges, a high reflection film 28 is disposed. The high reflection film 28 is a four-layer film composed of two Al₂O₃ films 24 and two a-Si films 26 that are alternately formed. The Al₂O₃ film 24 and the a-Si film 26 have a film thickness of λ/4 n₁ (where λ is 720 nm and n₁ represents the refractive index of the Al₂O₃ film) and a film thickness of λ/4 n₂ (where λ is 720 nm and n₂ represents the refractive index of the a-Si film), respectively, for a wavelength of around 720 nm, which is an intermediate value of 650 nm and 780 nm. The reflectivity of the high reflection film 28 is 93%.

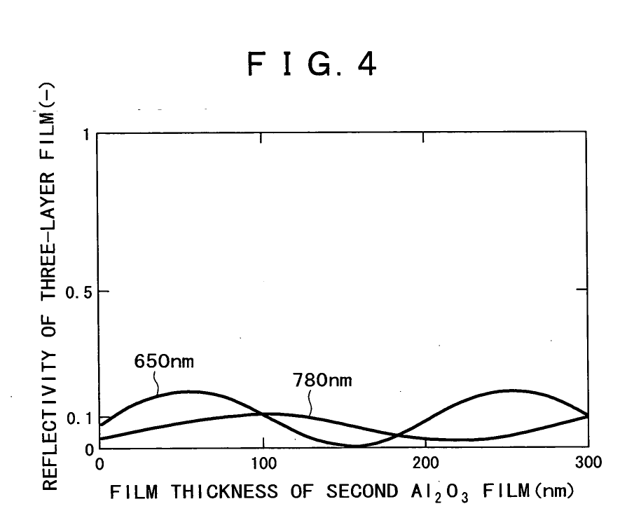

As is clear from FIG. 4 that shows the relationship between the film thickness of the second Al₂O₃ film 34 and the reflectivity of the three-layer dielectric film, the low reflection film 36 has a low reflectivity of 10% for both oscillation wavelengths of 650 nm and 780 nm.

FIG. 4 is a graph showing the reflectivity of the three-layer dielectric film for wavelengths of 650 nm and 780 nm with a parameter of the film thickness of the second Al₂O₃ film 34 in the case that the film thickness of the first Al₂O₃ film 16 and the film thickness of the TiO₂ film 18 are set to 30 nm and 50 nm, respectively.

Assuming that like the foregoing low reflection film 36, the film thicknesses of the first Al₂O₃ film 30 and the TiO₂ film 32 are set to 30 nm and 50 nm, respectively and unlike the low reflection film 36, the film thickness of the second Al₂O₃ film 34 is set to 150 nm, from the graph shown in FIG. 4, as the low reflection film, a three-layer dielectric film having a reflectivity of 1% or less for a wavelength of 650 nm or a reflectivity of around 8% for a wavelength of 780 nm can be obtained.

In addition, assuming that like the low reflection film 36, the film thicknesses of the first Al₂O₃ film 30 and the TiO₂ film 32 are set to 30 nm and 50 nm, respectively, and unlike the low reflection film 36, the film thickness of the second Al₂O₃ film 34 is set to 200 nm, from the graph shown in FIG. 4, as the low reflection film, a three-layer dielectric film having a reflectivity of around 8% for a wavelength of 650 nm and a reflectivity of around 3% for a wavelength of 780 nm can be obtained.

(Third Embodiment—Method for Producing Multiple Wavelength Semiconductor Laser)

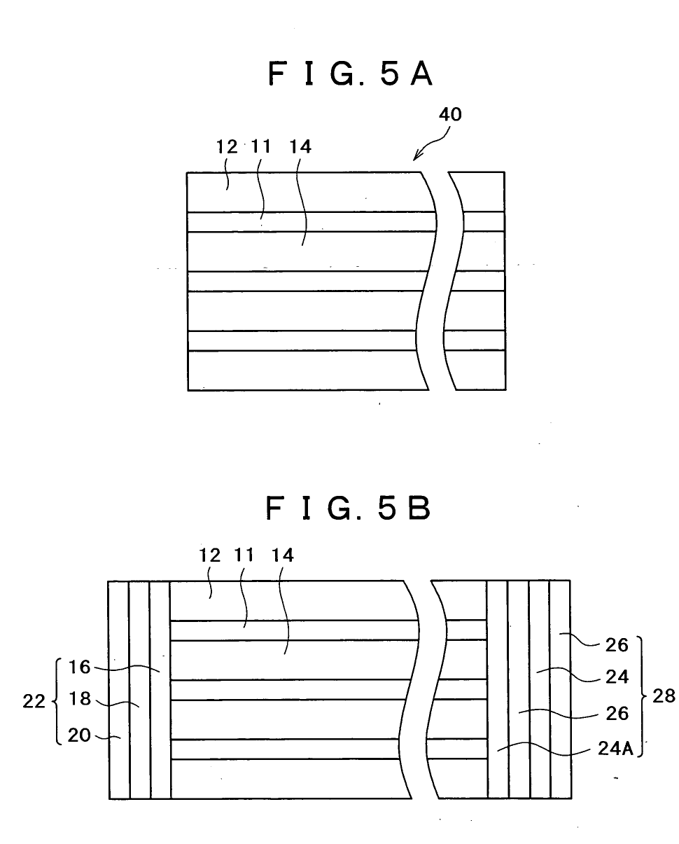

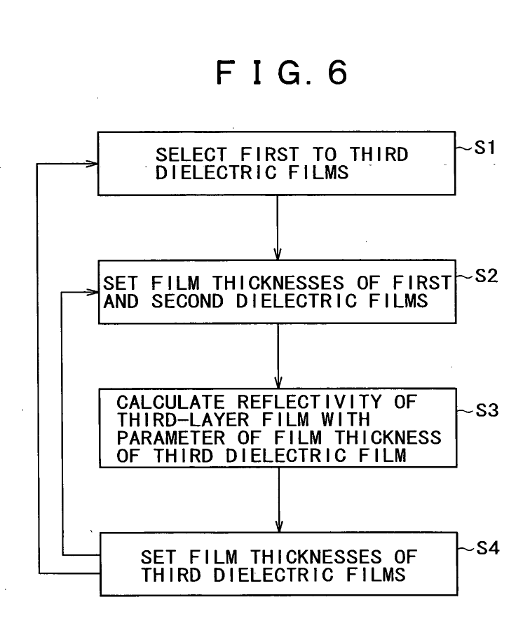

A third embodiment of the present invention is a method for producing the multiple wavelength semiconductor laser according to the first embodiment. FIG. 5A and FIG. 5B are sectional views showing the multiple wavelength semiconductor laser according to the first embodiment at two producing steps. FIG. 6 is a flow chart showing steps at which the structure of the low reflection film is set according to the third embodiment.

In a conventionally known method for producing a multiple wavelength semiconductor laser, for example, a producing method disclosed in, for example, Japanese Patent Application Publication No. 2001-244572, a first edge emitting type resonator structure 12 having an oscillation wavelength of 650 nm and a second edge emitting type resonator structure 14 having an oscillation wavelength of 780 nm are formed on a wafer.

Thereafter, the wafer on which the first edge emitting type resonator structure 12 and the second edge emitting type resonator structure 14 have been formed is cleaved. As shown in FIG. 5A, a laser bar 40 is formed.

According to the third embodiment, a common low reflection film is disposed on light emitting edges of the first edge emitting type resonator structure 12 and the second edge emitting type resonator structure 14. The low reflection film has a reflectivity of 15% or less for wavelengths of 650 nm and 780 nm. The low reflection film is a three-layer film composed of a first dielectric film, a second dielectric film, and a third dielectric film.

To dispose the common low reflection film, which is a three-layer dielectric film, composed of the first dielectric film, the second dielectric film, and the third dielectric film, as shown in FIG. 6, at step S₁, the first and third dielectric films are selected. Thereafter, a dielectric film that has a refractive index larger than that of the first dielectric film and that of the third dielectric film is selected as the second dielectric film. For example, as the dielectric film, any one of an Al₂O₃ film, a SiNₓ film, a TiO₂ film, a SiO₂ film, a SiC film, and a GaN film is selected. At the time of selecting the second dielectric film, a dielectric film having a refractive index that is larger than that of the first dielectric film and that of the third dielectric film is selected. The types and film thicknesses of the dielectric films are selected and set in accordance with data obtained through experience, experiments, and so forth..

According to the third embodiment, an Al₂O₃ film is selected as the first dielectric film to be a first Al₂O₃ film 16, a TiO₂ film as the second dielectric film to be a TiO₂ film 18, and another Al₂O₃ film Al₂O₃ film as the third dielectric film to be a second Al₂O₃ film 20.

Subsequently, at step S2, the film thicknesses of the first Al₂O₃ film 16 and the TiO₂ film 18 are determined. It is preferred that the film thicknesses of the first and second dielectric films should be set to 20 nm or more and 100 nm or less. According to the third embodiment, the film thicknesses of the first Al₂O₃ film 16 and the TiO₂ film 18 are set to 60 nm and 55 nm, respectively.

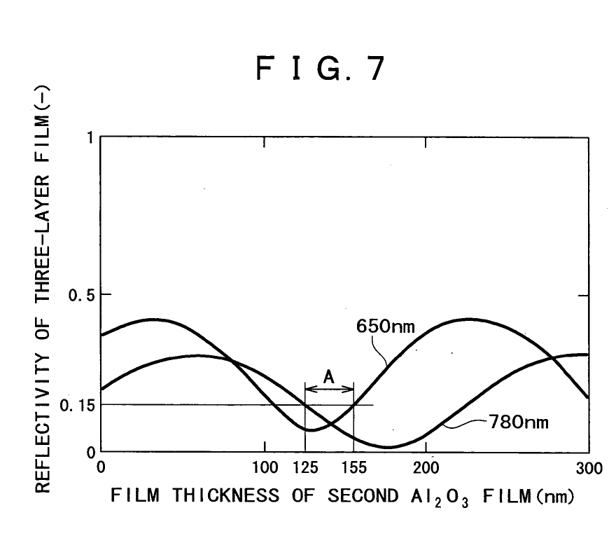

Thereafter, at step S₃, with a parameter of the film thickness of the second Al₂O₃ film 20, the reflectivity of the three-layer dielectric film for wavelengths of 650 nm and 780 nm is calculated. With the calculated result, a graph that shows the relation between the film thickness of the second Al₂O₃ film 20 and the reflectivity of the three-layer dielectric film is created as shown in FIG. 7 (that is the same graph as FIG. 2).

Thereafter, at step S₄, in accordance with the graph shown in FIG. 7, the film thickness of the second Al₂O₃ film 20 for a reflectivity of 15% or less for both wavelengths of 650 nm and 780 nm is obtained. As is clear from FIG. 7, the film thickness of the second Al₂O₃ film 20 for a reflectivity of 15% or less for both the wavelengths is in the range from 125 nm to 155 nm as denoted by “A” in FIG. 7. According to the third embodiment, if the film thickness of the second Al₂O₃ film 20 is set to 140 nm, a low reflection film 22 having a reflectivity of around 10% for both wavelengths of 650 nm and 780 nm can be designed.

In a case where the relationship between the film thickness of the second Al₂O₃ film 20 and the reflectivity of the three-layer dielectric film does not satisfy the predetermined value of the reflectivity for each oscillation wavelength at step S₄, the flow returns to step S₂. At step S₂, at least one of the film thicknesses of the first Al₂O₃ film 16 and the TiO₂ film 18 is newly set. At step S₃, the reflectivity of the three-layer dielectric film is calculated. At step S₄, the film thickness of the second Al₂O₃ film 20 that has a reflectivity of 15% or less for wavelengths of 650 nm and 780 nm is set.

In a case where the relationship between the film thickness of the second Al₂O₃ film 20 and the reflectivity of the three-layer dielectric film does not satisfy the predetermined value of the reflectivity for each oscillation wavelength, the flow returns to step S₁. At step S₁, the first dielectric film to third dielectric film are selected again. Until the predetermined value of the refractive index is obtained, the cycle from step S₁ to step S₄ is repeated.

Thereafter, as shown in FIG. 5B, on a cleaved facet of a laser bar 40, obtained by exposing light emitting edges of an edge emitting type resonator structure 12 and an edge emitting type resonator structure 14, the first Al₂O₃ film 16 of 60 nm, the TiO₂ film 18 of 55 nm, and the second Al₂O₃ film 20 of 140 nm are successively formed by the CVD. As a result, a low reflection film 22 is formed.

On the cleaved facet at the rear edge side opposite to the light emitting edges, a four-layer film composed of two Al₂O₃ films 24 and two a-Si films 26 that are alternately layered is formed by the CVD method. Each of the Al₂O₃ film 24 has a film thickness of λ/4 n₁ (where λ is 720 nm and n₁ is the refractive index of the Al₂O₃ film). Each of the a-Si films 26 has a film thickness of λ/4 n₂ (where λ is 720 nm and n₂ is the refractive index of the a-Si film). As a result, a high reflection film 28 is formed.

Consequently, a multiple wavelength semiconductor laser that has a low reflection film disposed on the light emitting edges and having a desired low reflectivity can be produced.

According to the third embodiment, with a three-layer dielectric film as a low reflection film, since the number of variables that can be used for designing the low reflection film is increased. Therefore, properly setting the variables makes it possible that an absolute value and a phase of the reflectivity of a low reflection film be easily designed within a wide range.

According to the foregoing embodiments, as a combination of materials of dielectric films, a structure of Al₂O₃/TiO₂/Al₂O₃ was exemplified. However, as long as the material of a dielectric film that has a refractive index higher than those of the first dielectric film and the third dielectric film is selected as the second dielectric film, the materials of the first to third dielectric films can be freely selected.

In addition, according to the foregoing embodiments, as oscillation wavelengths of a semiconductor laser element, 650 nm and 780 nm were exemplified. However, according to the present invention, the oscillation wavelengths are not restricted. In accordance with the characteristic of each semiconductor laser element disposed in the multiple wavelength semiconductor laser, the structure of the low reflection film that satisfies the desired reflectivity can be selected.

The foregoing describes the principles of the invention. Thus, it will be noted that although not explicitly described or shown herein, those skilled in the art will be able to devise various modifications which embody the principles of the invention and are within the spirit and scope of the following claims.

What is claimed is:

1. A multiple wavelength semiconductor laser monolithically having a plurality of edge emitting type semiconductor laser devices having different wavelengths, wherein:
a common low reflection multiple layer film that is a three-layer dielectric film comprised of a first dielectric film, a second dielectric film, and a third dielectric film that are successively formed outwardly, the common low reflection film being formed to have a same film thickness is provided on light emitting facets of said plurality of edge emitting type semiconductor laser devices, and
a refractive index of said second dielectric film is larger than a refractive index of said first dielectric film and a refractive index of said third dielectric film.

2. The multiple wavelength semiconductor laser as set forth in claim 1, wherein:
each of said first dielectric film to said third dielectric film is one of an Al₂O₃ film, a SiNₓ film, a SiO₂ film, a SiC film, an AlN film, and a GaN film.

3. The multiple wavelength semiconductor laser as set forth in claim 1, wherein:
an oscillation wavelength of said plurality of edge emitting type semiconductor laser devices is any one of a 650 nm band, a 780 nm band, and a 850 nm band.

4. The multiple wavelength semiconductor laser as set forth in claim 2, wherein:
an oscillation wavelength of said plurality of edge emitting type semiconductor laser devices is any one of a 650 nm band, a 780 nm band, and a 850 nm band.

5. A method for manufacturing a multiple wavelength semiconductor laser monolithically having a plurality of edge emitting type semiconductor laser devices having different wavelengths, the method comprising the steps of:
at a time of forming a laser bar by cleaving a wafer on which a resonator structure is formed and providing a common low reflection film on a light emitting facet of said plurality of edge emitting type semiconductor laser devices exposed on one cleaved facet of the laser bar,
(1) selecting a first dielectric film and a third dielectric film and then a dielectric film as a second dielectric film having a refractive index that is larger than a refractive index of the first dielectric film and a refractive index of the third dielectric film so as to dispose a three-layer dielectric film composed of said first dielectric film, said second dielectric film, and said third dielectric film as said common low reflection film;
(2) determining the film thicknesses of said first dielectric film and said second dielectric film;
(3) calculating a reflectivity for said three-layer dielectric film for oscillation wavelengths of said plurality of edge emitting type semiconductor laser devices with a parameter of a film thickness of said third dielectric film so as to obtain a relationship between the film thickness of said third dielectric film and the reflectivity of said three-layer dielectric film; and
(4) selecting the film thickness of said third dielectric film in accordance with the relation between the film thickness of said third dielectric film and the reflectivity of said three-layer dielectric film so that the reflectivity of said three-layer dielectric film for the oscillation wavelengths of said plurality of edge emitting type semiconductor laser devices satisfies a predetermined value or less.

6. The method for producing said multiple wavelength semiconductor laser as set forth in claim 5, wherein:
the step (1) includes a step of selecting as each of said first dielectric film to said third dielectric film an Al₂O₃ film, a SiNₓ film, a SiO₂ film, a SiC film, an AlN film, or a GaN film.

7. The method for producing said multiple wavelength semiconductor laser as set forth in claim 5, wherein:
the oscillation wavelengths of said plurality of edge emitting type semiconductor laser devices are any one of a 650 nm band, a 780 nm band, and a 850 nm band.

8. The method for producing said multiple wavelength semiconductor laser as set forth in claim 5, further comprising the steps of:
in a case where the relationship between the film thickness of said third dielectric film and the reflectivity of said three-layer dielectric film obtained at the step (3) does not satisfy the predetermined value or less of the reflectivity for the oscillation wavelengths at the step (4),
(5) returning to the step (2) and determining another value of at least either one of the film thickness of said first dielectric film and the film thickness of said second dielectric film; and
(6) advancing to the step (3) and the step (4) and repeating a cycle of the step (2) to the step (4) until the film thickness of said third dielectric film can be selected so that the reflectivity for the oscillation wavelengths satisfies the predetermined value or less.

9. The method for producing said multiple wavelength semiconductor laser as set forth in claim 8, further comprising the step of:
in a case where the relationship between the film thickness of said third dielectric film and the reflectivity of said three-layer dielectric film does not satisfy the predetermined value or less of the reflectivity for the oscillation wavelengths at the step (6),
(7) returning to the step (1), selecting another dielectric film as at least any one of said first dielectric film to said third dielectric film of said three-layer dielectric film, and repeating the cycle of the step (2) to the step (4).

10. The method for producing said multiple wavelength semiconductor laser as set forth in claim 9, further comprising the step of:
in a case where the relationship between the film thickness of said third dielectric film and the reflectivity of said three-layer dielectric film does not satisfy the predetermined value or less of the reflectivity for the oscillation wavelengths at the step (7),
(8) returning to the step (1), selecting another dielectric film as at least one of said first dielectric film to said third dielectric film of said three-layer dielectric film, and repeating the cycle of the step (2) to the step (4).
